(19) United States
(12) Patent Application Publication
(10) Pub. No.: US 2006/0125112 A1
(43) Pub. Date: Jun. 15, 2006

(54) Apparatus and method for manufacturing semiconductor device

(76) Inventors: Yukihiro Ikeya, Yokohama-shi (JP); Kazumi Ootani, Ibo-gun (JP); Motojiro Shibata, Yokohama-shi (JP); Yuusuke Miyamoto, Yokosuka-shi (JP)

Correspondence Address: OBLON, SPIVAK, MCCLELLAND, MAIER & NEUSTADT, P.C., 1940 DUKE STREET, ALEXANDRIA, VA, 22314, US

(21) Appl. No.: 11/280,329

(22) Filed: Nov. 17, 2005

(30) Foreign Application Priority Data
Nov. 19, 2004 (JP) 2004-336034

(51) Int. Cl. H01L 23/48

(52) U.S. Cl. 257/778

(57) ABSTRACT

An apparatus for manufacturing a semiconductor device comprises a planarization mechanism section which pressurizes a top of a bump that is provided onto at least one of a substrate and a semiconductor chip and makes the top of the bump flat, and a bonding mechanism section which bonds the substrate with the semiconductor chip via the bump whose top has been made flat by the planarization mechanism section. The planarization mechanism section has a bump recognition camera which takes an image of bumps, a planarization tool with a pressurizing surface which pressurizes the top of the bump, and a driving mechanism which controls to move the planarization tool to a position of the bump detected by the bump recognition camera, the driving mechanism comprising a pressurization mechanism which presses the pressurizing surface of the planarization tool against the bump.

### CROSS-REFERENCE TO RELATED APPLICATIONS

This application is based upon and claims the benefit of priority from prior Japanese Patent Application No. 2004-336034, filed Nov. 19, 2004, the entire contents of which are incorporated herein by reference.

### BACKGROUND OF THE INVENTION

1. Field of the Invention

The present invention relates to an apparatus and method for manufacturing a semiconductor device by carrying out so-called flip chip bonding which connects electronic parts and a substrate via bumps.

2. Description of the Related Art

In Jpn. Pat. Appln. KOKAI Publication No. 2004-103603, there is disclosed, as a method for manufacturing a semiconductor device, a so-called flip chip bonding system in which a bump is formed on a substrate, and the substrate is bonded with a semiconductor chip which is an electronic part via the bump.

More specifically, in timing when the substrate on which a bump is provided at a predetermined portion thereof is conveyed to a bonding stage, a pickup inversion tool takes out one semiconductor chip from semiconductor chips to be mounted on a wafer stage.

Then, the pickup inversion tool inverts the semiconductor chip so as to be in a face-down (downward) direction, and delivers it to a bonding head. At the bonding head, a bonding tool absorbs the semiconductor chip, and carries out bonding of the semiconductor chip onto the substrate via the bump.

Although there is no description in the above-described Jpn. Pat. Appln. KOKAI Publication No. 2004-103603, a method by so-called wire bonding is used in order to provide the bump on the substrate. To describe the wire bonding method concretely, a wire is inserted into a hole portion of a capillary, and the tip of the wire is projected from the tip portion of the capillary.

Then, the tip of the wire is heated to be melted, and is formed in a ball shape, and thermocompression bonding for pressing the ball portion against a predetermined region of the substrate is carried out so as to be firmly fixed to the substrate. Next, the wire is cut off by moving the capillary so as to draw, for example, a loop orbit.

In a manner of speaking, a state is formed in which the wire portion fastened to the substrate is plucked away by intricately moving the capillary. Accordingly, in many cases, so-called beard-shaped protrusion remains so as to be made solid on the surface (top) of the bump formed on the substrate.

Naturally, the presence or absence of a protrusion, and the shape thereof, and a dimension in height from the bottom of the bump to the tip of the protrusion are formed so as to be different at each bump. When a semiconductor chip is made to contact such a bump, a state may be brought about in which the semiconductor chip is inclined due to a difference among the dimensions in heights of the bumps even if the positions of the semiconductor chip and the bump correspond to each other.

Therefore, the semiconductor chip is slipped during the bonding to bring about displacement or rotation thereof, which could lead to being incapable of bonding. This phenomenon is especially-pronounced in a bonding method simultaneously using ultrasonic waves, and in a case in which a size of the semiconductor chip is small, which adversely affects the production efficiency.

### BRIEF SUMMARY OF THE INVENTION

The present invention has been achieved in consideration of the above-described circumstances, and an object of the present invention is to provide an apparatus for manufacturing a semiconductor device, which contributes to an increase in the productivity by forming bumps in optimum shapes for carrying out bonding of a semiconductor chip and a substrate via the bumps, and to provide a method for manufacturing a semiconductor device, which can obtain an increase in the productivity by improving the position recognizing accuracy for a substrate, and the detection accuracy for bumps.

In order to achieve the above object, an apparatus for manufacturing a semiconductor device, according to the present invention, comprises: recognition means for detecting a position of a bump by taking an image of the bump; a planarization tool with a pressurizing surface which pressurizes a top of the bump; a driving mechanism which controls to move the planarization tool to the position of the bump detected by the recognition means, and which comprises pressurization means for pressurizing the pressurizing surface of the planarization tool against the bump; and bonding means for bonding a substrate with electronic parts via the bump whose top has been made flat by the planarization tool.

In order to achieve the above object, a method for manufacturing a semiconductor device, according to the present invention, in which electronic parts are bonded via a bump provided on a substrate, the method comprising: a step of setting a predetermined region on a monitor screen as a position recognition pattern with respect to the substrate, and setting a plurality of reference points so as to be separated from the position recognition pattern, and at sides outer than bumps which are provided at outermost sides on the substrate; a step of simultaneously carrying out position recognition of the substrate and detection of the presence or absence of bumps on the substrate; a step of, when an error in detecting bumps is brought about due to some of the bumps provided on the substrate being out of the monitor screen, obtaining an amount of displacement of the substrate by calculating positions of the reference points on the basis of a result of the position recognition of the substrate; and a step of shifting the recognition pattern and the reference points so as to be within the monitor screen by moving the recognition position so as to correspond to the amount of displacement of the substrate obtained in the above step.

According to the present invention, the effect of contributing to an increase in the productivity is brought about by forming bumps in shapes optimum for flip chip bonding.

Additional objects and advantages of the invention will be set forth in the description which follows, and in part will be obvious from the description, or may be learned by practice of the invention. The objects and advantages of the invention may be realized and obtained by means of the instrumentalities and combinations particularly pointed out hereinafter.

### BRIEF DESCRIPTION OF THE SEVERAL VIEWS OF THE DRAWING

The accompanying drawings, which are incorporated in and constitute a part of the specification, illustrate embodiments of the invention, and together with the general description given above and the detailed description of the embodiments given below, serve to explain the principles of the invention.

FIG. 1 is an appearance perspective view schematically showing a semiconductor manufacturing apparatus in accordance with an embodiment of the present invention;

FIGS. 2A to 2E are views showing the processes from bump formation through planarization thereof up to recognition in order;

FIG. 3 is a plan view showing a state of bumps provided on wirings of a substrate in accordance with the embodiment;

FIG. 4 is a view of a monitor screen in a state in which normal position recognition of a substrate and detection of the presence or absence of bumps are simultaneously carried out in accordance with the embodiment;

FIG. 5 is a view of a monitor screen in a state in which the position of the substrate is shifted from the monitor screen in accordance with the embodiment;

FIG. 6 is a view of a monitor screen in a state in which the substrate and the bumps have been returned to the normal position in accordance with the embodiment; and

FIG. 7 is a flowchart of recognition in accordance with the embodiment.

### DETAILED DESCRIPTION OF THE INVENTION

Hereinafter, an embodiment of the present invention will be described in detail with reference to the drawings.

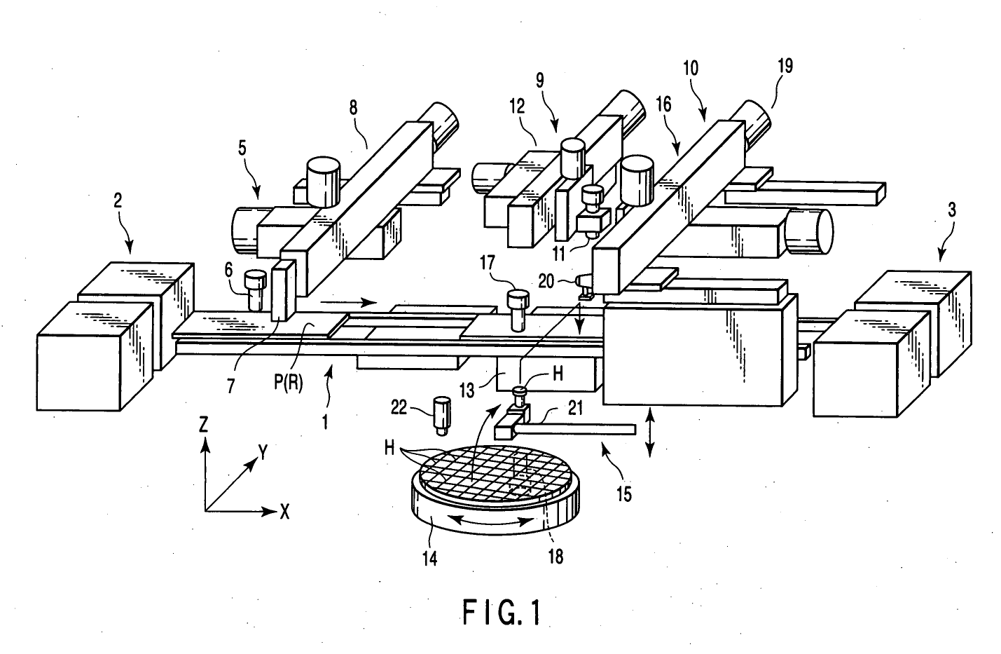

FIG. 1 is a schematic perspective view showing a semiconductor device with a part thereof omitted.

A carrier line 1 is provided which forms a straight carrier belt or a conveyance feed pawl structure, and in which a conveyance direction in which a substrate P is conveyed from the left end to the right end in the drawing has been set. A loader mechanism 2 which supplies the substrate P to the carrier line 1 is disposed at the left side and of the carrier line 1. An unloader mechanism 3 which takes out the substrate P having a semiconductor chip H mounted thereon as will be described later is disposed at the right side end.

Bumps B are provided on predetermined regions on wirings R in the substrate P to be supplied by the loader mechanism 2, and the substrate P having the bumps B is conveyed to the carrier line 1. A planarization mechanism section (planarization means) 5 for processing the top of the bumps B is disposed onto the substrate P which is conveyed by the carrier line 1 from the loader mechanism 2.

The planarization mechanism section 5 has a bump recognition camera (recognition device) 6 which takes an image of the bumps B, and a planarization tool 7 which makes the bumps B flat. As a material constituting the planarization tool 7, a base material that is before grinding vapor phase synthetic diamond is used, and the surface roughness of the tip face thereof (arithmetic average roughness: Ra) is set to, for example, 0.3 μm. The planarization tool 7 is controlled to drive in X, Y, and Z directions, and is supported by a driving mechanism 8 having a pressurization mechanism.

Along the conveyance direction of the carrier line 1 of the planarization mechanism section 5, a recognition mechanism section 9 and a bonding mechanism section (bonding means) 10 are provided. The recognition mechanism section 9 recognizes the substrate P and the semiconductor chip H. The bonding mechanism section 10 carries out flip chip bonding of the substrate P and the semiconductor chip H via the bumps B.

To describe the bonding mechanism 10 first, the bonding mechanism 10 comprises: a bonding stage 13 which is disposed at a portion directly below the carrier line 1; a wafer stage 14 which is disposed at the side portion of the carrier line 1 separated from the bonding stage 13; a chip inversion unit 15 which is interposed between the wafer state 14 and the bonding stage 13; and a bonding head 16 which is disposed at a portion above the bonding stage 13.

The bonding stage 13, in place of the carrier line 1, supports the substrate P on the carrier line 1. The bonding head 16 disposed on the bonding stage 13 via the carrier line has a bonding tool 20, and the bonding tool 20 is supported so as to freely move in the X, Y, and Z directions and the 0 direction by a driving mechanism 19.

The wafer stage 14 has an XY table successively provided on the base (the both are not illustrated), and a θ table. On the θ table, many semiconductor chips H which have been divided are mounted as electronic parts in a state of being pasted in a sheet (not shown).

The chip inversion unit 15 has a pickup inversion tool 21 formed in a substantially L shape. The pickup inversion tool 21 has a nozzle which vacuum-absorbs the semiconductor chip H at the tip portion thereof. The proximal portion of the pickup inversion tool 21 is freely rotatable and displaceable within a range up to the horizontal direction that the nozzle rotates 180 degrees from the horizontal direction, and is driven in the Z direction.

Note that the bonding tool 20 is set such that the portion for absorbing the semiconductor chip H is made to be equivalent with or to be slightly larger or smaller than the external diameter of the semiconductor chip H in order to be able to absorb and maintain the semiconductor chip H so as to be stable.

The recognition mechanism section 9 has a substrate recognition camera 11 pointing at the substrate P on the bonding stage 13, a rear face recognition camera 17 and a chip recognition camera 18 which are provided at positions adjacent to the bonding head 16, and a wafer recognition camera 22 which is disposed at an region above the wafer stage 14.

The substrate recognition camera 11 is supported by the driving mechanism 12, can be driven in the X, Y, and Z directions relatively with respect to the substrate P on the bonding stage 13, and is provided so as to take and image of the substrate P. The rear face recognition camera 17 is provided so as to take an image of the semiconductor chip H supported such that an electrode portion thereof is directed downward (face-down) by the chip inversion unit 15. The chip recognition camera 18 is provided so as to take an image of the semiconductor chip H delivered from the chip inversion unit 15 to the bonding head 16. The wafer recognition camera 22 is provided so as to take an image of the semiconductor chip H on the wafer stage 14.

All image-pickup signals which are respectively imaged by the bump recognition camera 6 provided to the planarization mechanism 5, and the substrate recognition camera 11, the rear face recognition camera 17, the chip recognition camera 18, and the wafer recognition camera 22 which constitute the recognition mechanism section 9, are transmitted to an image recognition control section, and binarization image processing by threshold values of black and white is applied thereon. Processing results at the image recognition control section are inputted to a control device (not shown), and it is configured such that a control signal is transmitted from the control device to a corresponding mechanism section so as to be subjected to necessary control.

In such a semiconductor manufacturing apparatus, on the wirings R of the substrate P to be supplied from the loader mechanism 2 to the carrier line 1, the bumps B as will be described hereinafter are provided by a bump forming mechanism (not shown).

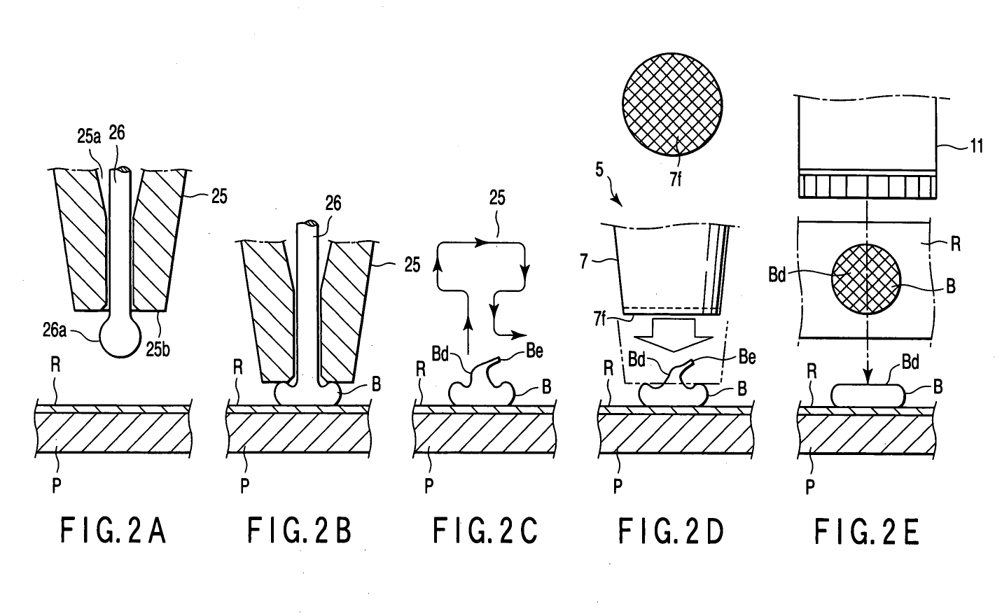

Namely, as shown in FIG. 2A, an Au wire 26 is inserted into a hole portion 25a of a capillary 25, and the tip of the wire is projected from a tip face 25b of the capillary 25. In this state, electric discharge with respect to the Au wire 26 is carried out by operating an electric torch (not shown), which forms an Au ball 26a. The diameter of the Au ball 26a becomes a size of about double to triple of the diameter of the wire 26.

As shown in FIG. 2B, the capillary 25 is let down, so that the Au ball 26a formed at the tip of the Au wire 26 is pressed against a predetermined region on a substrate lead frame R under a predetermined pressurizing force, and the capillary 25 is ultrasonic-vibrated. The Au ball 26a is fastened onto the substrate lead frame R by thermocompression bonding while using ultrasonic waves, which forms the bottom of the bump B.

As shown in FIG. 2C, the Au wire 26 is cut off by moving the capillary 25 in the horizontal direction after being moved in the vertical direction so as to draw a loop orbit above the bottom of the bump B. In this state, a top Bd is formed on the top surface of the bottom of the bump B. However, in some cases, the bump B is formed such that, for example, a beard-shaped protrusion Be remains at the top Bd of the bump.

As shown in FIG. 1 again, the substrate P having the bump B described above is supplied from the loader mechanism 2 to the carrier line 1, and is conveyed. When the substrate P is conveyed to a position facing the bump planarization mechanism section 5, the recognition camera 6 operates so as to take an image of the bump B on the substrate P. The image-pickup signal of the recognition camera 6 is transmitted to the image recognition control section to be subjected to image processing, and positioning of the planarization tool 7 with respect to a bump B is carried out. Namely, the carrier line 1 is stopped, and the driving mechanism 8 supporting the planarization tool 7 operates in the X and Y directions.

As shown in FIG. 2D, after the positioning of the planarization tool 7 is carried out, the planarization tool 7 descends (moves in the Z direction) to contact the bump top Bd, and further applies pressure at a predetermined pressure. As described above, the base material that is before grinding vapor phase synthetic diamond is used as the planarization tool 7, and the surface roughness of a tip face 7f thereof (arithmetic average roughness: Ra) is set to 0.3 μm. Accordingly, the beard-shaped protrusion Be projected at the bump top Bd is crushed flatly to be deformed flat.

FIG. 2D shows a state in which one planarization tool 7 makes one bump B flat. However, in practice, in order to increase the productivity, one planarization tool 7 simultaneously makes a plurality of bumps B flat.

With the bump B provided on the wiring R of the substrate P, a dimension in height from the bottom of the bump B to the tip of the beard-shaped protrusion Be is about 70 μm. However, the bump top Bd is made flat due to the beard-shaped protrusion Be being crushed flatly by means of the planarization tool 7, whereby, the bump B is deformed such that the dimension in height from the bottom to the top Bd is about 50 μm. On the surface of the planarized top Bd, a rough shape is left as the surface roughness at the tip face 7f of the planarization tool 7 is.

The conveyance of the substrate P is started again after the planarization of the bump top Bd by the planarization tool 7 is completed, and as shown in FIG. 2E, the conveyance of the substrate P substrate P is stopped when the positions of the bumps B reach a portion below the substrate recognition camera 11. The substrate recognition camera 11 takes an image of the wirings R provided on the substrate P, and recognizes the position of the substrate P. At the same time, the substrate recognition camera 11 takes an image of the bumps B provided on the substrate P, and detects the presence or absence of the bumps B.

At that time, because the numeric value of the surface roughness is set with respect to the tip face 7f of the planarization tool 7, surface roughness is formed as it is at the top Bd of the bump B. Accordingly, the bump top Bd diffusely reflects an illumination light, and the image recognition control section recognizes the bump B so as to be almost black.

In contrast thereto, the portions of the wirings R which are bump forming surfaces of the substrate P on which the bumps B are to be formed are formed by applying nickel plating processing onto, for example, a sheet of copper material, and is shiny. Accordingly, the surfaces of the wirings R of the substrate P totally reflect an illumination light, and the image recognition control section recognizes those so as to be almost white.

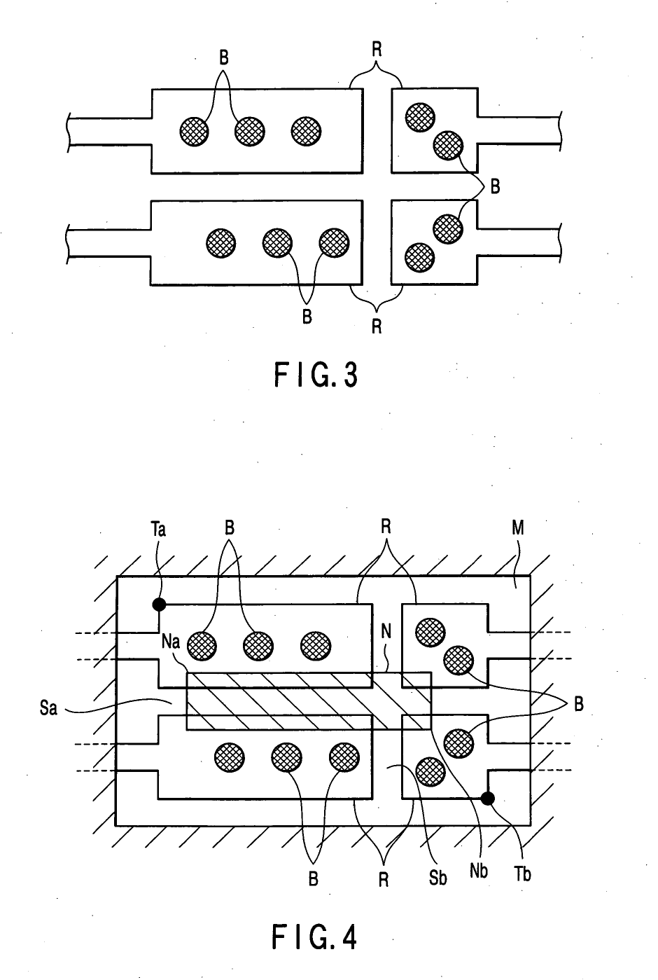

Namely, as shown in FIG. 3, the state of the brightness and darkness of the bumps B with respect to the wirings R on the substrate P is made extremely clear, and the presence or absence of the bumps B is exactly detected, so that improvement in recognition efficiency can be obtained. A rate of incidence of recognition errors is greatly reduced, which can lead to an increase in the apparatus availability.

As shown in FIG. 1 again, the semiconductor chips H on the wafer stage 14 are imaged by the wafer recognition camera 22, and a semiconductor chip H to be absorbed by the pickup inversion tool 21 is positioned on the basis of the image-pickup signals. Namely, positioning is carried out for the directions of the X and Y tables and the θ table which support the wafer stage 14.

The pickup inversion tool 21 operates to absorb the semiconductor chip H on the wafer stage 14, and invert it 180°. The rear face recognition camera 17 takes an image of this state, and transmits the image-pickup signal to the image recognition control section. The semiconductor chip H recognized by the rear face recognition camera 17 is delivered to the bonding tool 20 provided to the bonding head 16 on the basis of the result of image-pickup of the rear face recognition camera 17.

The semiconductor chip H delivered to the bonding tool 20 is imaged by the chip recognition camera 18, and the image-pickup signal thereof is transmitted to the image recognition control section. As described above, the position of the substrate P on the bonding stage 13 is recognized by the substrate recognition camera 11. Consequently, a position of bonding of the semiconductor chip H on the substrate P is determined, and positioning of the bonding head 16, i.e., positioning of the semiconductor chip H is carried out on the basis of the determination.

The bonding head 16 is driven so as to be directed to a position instructed in advance on the substrate P, and reaches the instructed position. Then, the bonding head 16 is located in the bonding position determined by the image recognition control section to descent, and the semiconductor chip H is bonded onto the substrate P. In this way, so-called flip chip bonding is carried out in which the semiconductor chip H is directly attached to the bumps B provided on the wirings R of the substrate P, so that a semiconductor device in which the semiconductor chip H is mounted on the substrate P is manufactured.

Note that, as described above, the substrate recognition camera 11 configuring the recognition mechanism section 9 takes an image of some parts of the wirings R provided on the substrate P, and recognizes the position of the substrate P. In addition the substrate recognition camera 11 takes an image of the bumps B on the wirings R, and detects the presence or absence of the bumps B.

More specifically, the magnification of the substrate recognition camera 11 is made extremely high, a part of the substrate P is projected on a monitor screen, and the bumps B are imaged together with the wirings R on the substrate P. However, in some cases, the position to which the substrate P is conveyed is shifted under some conditions, and a preset number of the bumps B to be projected on the monitor screen cannot be put within the monitor screen.

Even in such a state, the substrate recognition camera 11 takes an image and transmits an image-pickup signal to the image recognition control section, in which binarization image processing is carried out to transmit a processed signal to the control device. At the control device, the number of the bumps B which is set and stored in advance is compared with the number of the bumps B which have been detected, and it is determined as an error in detecting bumps on the basis of a portion where the both are not the same. Under normal conditions, the driving of the apparatus is immediately stopped, and the conveyance of the substrate has to be redone, which is in danger of affecting the productivity.

Then, as will be described hereinafter, conditions for recognition are set, and thus, an attempt is made to dissolve a reduction in the productivity by avoiding the apparatus from being stopped due to an error in detecting bumps.

In other words, as shown in FIG. 4, the image-pickup signal imaged by the substrate recognition camera 11 is transmitted to the control device, and some parts of the wirings R on the substrate P and the bumps B provided thereon are projected on the monitor screen M on the basis of the transmitted image-pickup signal.

In the control device, the central portion on the monitor screen M is set in advance as a position recognition pattern N for the substrate P. In predetermined positions with respect to the position recognition pattern N, a first reference point Ta and a second reference point Tb which are shown as black circles in the drawing are set and stored.

For example, the position recognition pattern N is intended for some parts of the wirings R adjacent to each other, and a space S portion among those wirings R. In more detail, it is set such that a portion where an inter-wiring space Sa in the crosswise direction and an inter-wiring space Sb in the lengthwise direction on the screen cross to each other is located in a position which is shifted by a predetermined amount toward one side portion of the position recognition pattern N.

The first reference point Ta is separated by predetermined intervals in the X direction and the Y direction from-the upper left corner portion Na of the position recognition pattern N, and is set so as to be intended for a corner portion of the wiring R which is a region in the obliquely left direction. The second reference point Tb is separated by predetermined intervals in the X direction and the Y direction from the lower right corner portion Nb of the position recognition pattern N, and is set so as to be intended for a corner portion of the wiring R which is a region in the obliquely right direction. Namely, these first and second reference points Ta and Tb are separated from the position recognition pattern N, and are set at the sides outer than the bumps B provided at outermost side.

Then, position recognition of the substrate P and detection of the presence or absence of the bumps B on the wirings R are simultaneously carried out on the basis of the image-pickup signal by the substrate recognition camera 11. However, as described above, there are cases in which a conveying position of the substrate P with respect to the substrate recognition camera 11 is shifted under some conditions.

This state is shown in FIG. 5. Namely, the substrate recognition camera 11 takes an image of a state, which is a state projected on the monitor screen M, in which some parts of the wirings R and some of the bumps B on the substrate P, and for example, the second reference point Tb are out of the monitor screen M, and the substrate recognition camera 11 transmits the image-pickup signal to the image recognition control section.

The image recognition control section which has received the image-pickup signal carries out binarization image processing, and transmits the recognition signal to the control device. Here, the number of the bumps B on the monitor screen M is computed, and it is recognized that the result thereof does not reach a normal number of bumps stored in advance. Then, the presence of the first reference point Ta is confirmed on the monitor screen M, and it is confirmed that the second reference point Tb does not exist.

However, because the entire position recognition pattern N exists in the monitor screen M, at least a position recognition result with respect to the substrate P has been obtained. Then, the control device determines a position of the second reference point Tb which cannot be confirmed on the monitor screen M by an operation on the basis of the position recognition result with respect to the substrate P.

On the basis of the operation result, an amount of displacement of the substrate P is calculated, and an amount of movement of the position recognition camera 11 is obtained. Namely, the movement of the position recognition camera 11 is controlled such that the second reference point Tb is projected on the monitor screen M, and the position recognition pattern N is located in the central portion of the monitor screen M.

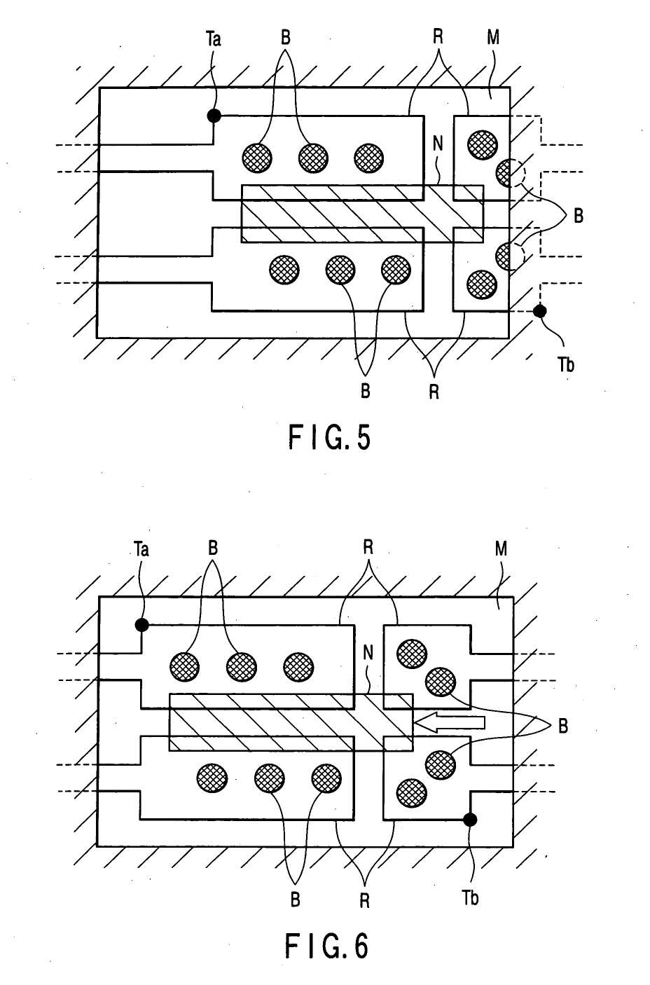

As shown in FIG. 6, the substrate recognition camera 11 is moved in the arrow direction in the drawing, and the position recognition pattern N is located in the central portion of the monitor screen M. Then, the first and second reference points Ta and Tb are projected on the monitor screen M, and the preset number of the bumps B are put within the monitor screen M.

Then, position recognition of the substrate P is carried out again, and detection of the presence or absence of bumps B is carried out. At that time, when a result that there are the preset number of the bumps B is obtained, the recognition of the position recognition camera 11 is completed, and the substrate P is conveyed to a position facing the bonding mechanism 10.

In the bonding mechanism 10, the semiconductor chip H absorbed by the bonding tool 20 is recognized by the chip recognition camera 18. Then, the bonding tool 20 is moved to the bonding position on the basis of the result that the substrate recognition camera 11 has recognized the substrate P and the bumps B, and the substrate P is bonded with the semiconductor chip H via the bumps B.

Accordingly, the position of the substrate P is shifted under some conditions, and the preset number of the bumps B cannot be recognized, which leads to an error in detecting bumps. Even in such a case, there is no need to immediately stop the apparatus, and an increase in the availability of the apparatus is obtained.

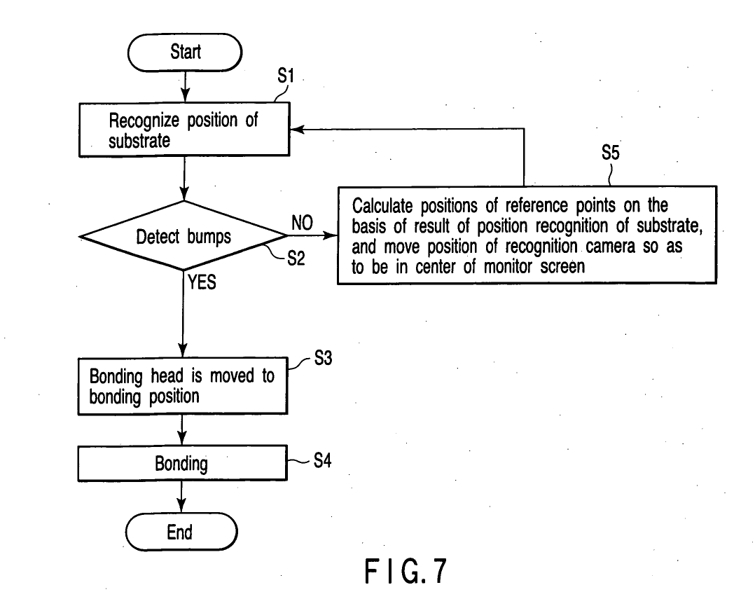

The above conditions for recognition will be described again on the basis of the flowchart shown in FIG. 7.

In step S1, position recognition of the substrate P is carried out on the basis of the position recognition pattern N set on the monitor screen M. At the same time as timing, the number of the bumps B is detected in step S2, and it is determined whether or not the number of the bumps B is the number set in advance. Namely, a calculation for the presence or absence of the number of bumps B which has been set is carried out.

When the detected result for the bumps B is YES, the routine proceeds to step S3. In the bonding mechanism 10, the semiconductor chip H absorbed by the bonding tool 20 is recognized by the chip recognition camera 18. Then, the bonding tool 20 is moved to the bonding position on the basis of the result that the substrate recognition camera 11 has recognized the substrate P and the bumps B, and the substrate P is bonded with the semiconductor chip H via the bumps B.

Further, in step S2, when some of the bumps B are made out of the monitor screen M due to, for example, the conveying position of the substrate P being shifted, and therefore, the result of the detection of the presence or absence of the bumps B is NO, the routine proceeds to step S5.

In the step S5, a position of a reference point in hiding (the second reference point Tb) is calculated on the basis of the position recognition result with respect to the substrate P, and the movement of the position recognition camera 11 is controlled such that the position recognition pattern N is located in the center of the monitor screen M on the basis of the calculated result.

Thereafter, the routine proceeds to step S1 again, in which position recognition of the substrate P is carried out, and in step S2, the presence or absence of the bumps B is detected. Here, when a detected result that there are a normal number of the bumps B (YES) is obtained, the routine proceeds to step S3. Conditions for stopping the apparatus are made little as much as possible by repeating retries for such a detection of the presence or absence of the bumps B.

Note that, in the above-described embodiment, the bumps B are provided on the wirings R on the substrate P. However, the present invention can be applied to a case in which the bumps B are provided on the semiconductor chip H, and can be applied to a case in which the bumps B are provided on the lead frame, and flip chip bonding of the semiconductor chip H is carried out.

Further, the present invention is not limited to the embodiment described above as is, and at the stage of implementing the invention, the components can be modified to be embodied within a range which does not deviate from the gist of the present invention. Then, various inventions can be formed by appropriately combining the plurality of components disclosed in the embodiment described above.

Additional advantages and modifications will readily occur to those skilled in the art. Therefore, the invention in its broader aspects is not limited to the specific details and representative embodiments shown and described herein. Accordingly, various modifications may be made without departing from the spirit or scope of the general inventive concept as defined by the appended claims and their equivalents.

What is claimed is:

1. An apparatus for manufacturing a semiconductor device, comprising:
detector which detects a position of a bump by taking an image of the bump;
a planarization tool with a pressurizing surface which pressurizes a top of the bump;
a controlling mechanism which controls to move the planarization tool to the position of the bump detected by the recognition means, and which comprises pressurization means for pressurizing the pressurizing surface of the planarization tool against the bump; and
bonding mechanism which bonds a substrate with electronic parts via the bump whose top has been made flat by the planarization tool.

2. The apparatus for manufacturing a semiconductor device, according to claim 1, wherein the bump pressurizing surface of the planarization tool is formed such that a surface roughness thereof is rougher than that of a surface of a portion on which the bump is provided.

3. A method for manufacturing a semiconductor device, in which electronic parts are bonded via a bump provided on a substrate, the method comprising:
setting a predetermined region on a monitor screen as a position recognition pattern with respect to the substrate, and setting a plurality of reference points so as to be separated from the position recognition pattern, and at sides outer than bumps which are provided at outermost sides on the substrate;
simultaneously carrying out position recognition of the substrate and detection of the presence or absence of bumps on the substrate;
when an error in detecting bumps is brought about due to some of the bumps provided on the substrate being out of the monitor screen, obtaining an amount of displacement of the substrate by calculating positions of the reference points on the basis of a result of the position recognition of the substrate; and
shifting the recognition pattern and the reference points so as to be within the monitor screen by moving the recognition position so as to correspond to the amount of displacement of the substrate obtained in the above step.

4. The method for manufacturing a semiconductor device, according to claim 3, wherein, after shifting the recognition pattern and the reference points so as to be within the monitor screen,
the process returns to the step of simultaneously carrying out position recognition of the substrate and detection of the presence or absence of bumps on the substrate again.
